(19) United States
(12) Patent Application Publication
(10) Pub. No.: US 2014/0060790 A1
(43) Pub. Date: Mar. 6, 2014

(54) HEAT SINK, MANUFACTURING METHOD THEREOF AND TESTING METHOD OF HEAT-DISSIPATING CAPABILITY

(71) Applicants: CHUNG-KAI SHYU, Tu-Cheng (TW); MING-HSIU CHUNG, Tu-Cheng (TW)

(72) Inventors: CHUNG-KAI SHYU, Tu-Cheng (TW); MING-HSIU CHUNG, Tu-Cheng (TW)

(21) Appl. No.: 13/649,626

(22) Filed: Oct. 11, 2012

(30) Foreign Application Priority Data
Sep. 3, 2012 (TW) 101132087

(51) Int. Cl. F28F 21/08; B23P 15/26; C25D 9/04; B05D 5/00; G01R 31/10; F28F 7/00

(52) U.S. Cl. 165/185; 324/750.09; 205/333; 427/256; 29/890.03

(57) ABSTRACT

An exemplary heat sink includes a heat-conducting substrate and a heat-conducting film formed on an outer surface of the substrate. A heat resistance of the heat-conducting film is lower than that of the heat-conducting substrate. A heat conductivity coefficient of the heat-conducting film is higher than that of the heat-conducting film. The heat-conducting film is thinner than the heat-conducting substrate, and a thickness of the heat-conducting film is in a range from about 0.025 mm to about 0.05 mm.

### BACKGROUND

1. Technical Field

The present disclosure relates to heat dissipation apparatus, and more particular to a heat sink dissipating heat generated from electronic components.

2. Description of Related Art

With a rapid development of electronic products, heat generated from electronic components of the electronic products become more and more. If the heat can not be removed rapidly, the electronic components are prone to be overheated. Generally, a heat sink and a fan are provided to dissipate heat generated from the electronic components. The heat sink is mounted on the electronic component and the fan is mounted on the heat sink. However, the electronic products become thinner and thinner, and a space in each electronic product is small. The conventional heat sink and the fan have a larger bulk, and are not suitable to the electronic product now.

What is needed, therefore, is an improved heat sink which can overcome the above described shortcomings.

### BRIEF DESCRIPTION OF THE DRAWINGS

FIG. 1 is a schematic, cross-sectional view of a heat sink according to an exemplary embodiment of the present disclosure

FIG. 2 is similar to FIG. 1, but showing the heat sink mounted on an electronic component.

FIG. 3 is a schematic view showing a substrate oxidized in a micro-arc oxidation device of a method for manufacturing the heat sink of FIG. 1.

FIG. 4 and FIG. 5 are schematic views showing steps of testing a heat-dissipating capability of the heat sink of FIG. 1 and a conventional aluminum plate.

### DETAILED DESCRIPTION

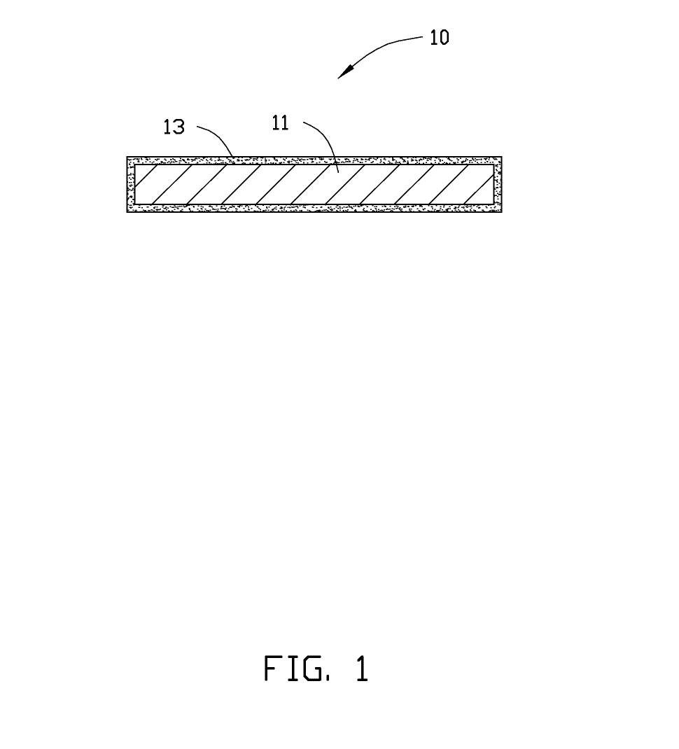

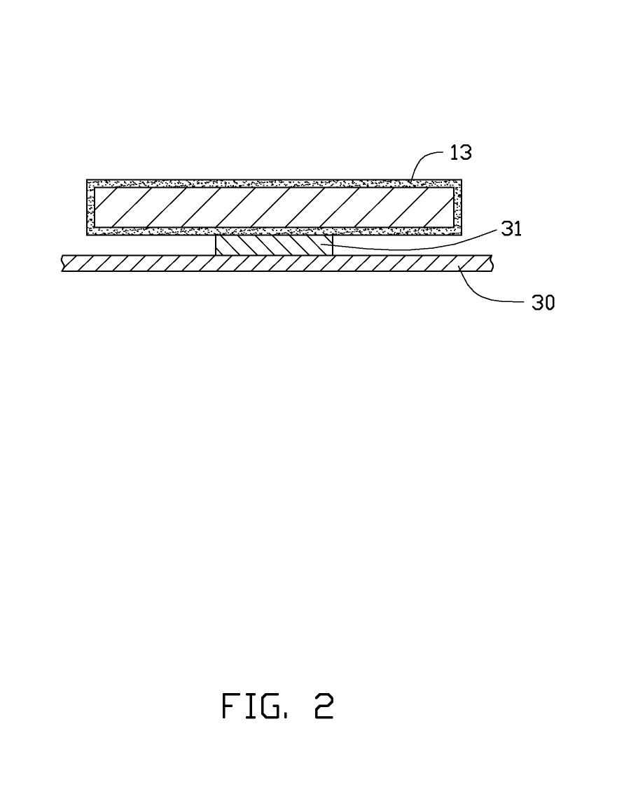

Referring to FIGS. 1 and 2, the heat sink 10 includes a heat-conducting substrate 11 and a heat-conducting film 13 formed on an outer periphery of the heat-conducting substrate 11. The heat-conducting substrate 11 is a rectangular plate with a uniform thickness. In this embodiment, the heat-conducting substrate 11 is an aluminum plate.

A heat conductivity coefficient of the heat-conducting film 13 is higher than that of the heat-conducting substrate 11. A heat resistance of the heat-conducting film 13 is lower than that of the heat-conducting substrate 11. The heat-conducting film 13 entirely covers the heat-conducting substrate 11, and is thinner than the heat-conducting substrate 11. The heat-conducting film 13 can be selected from a group consisting of ceramic, metal, metallic oxide and combination thereof, and can dissipate heat absorbed by the heat-conducting substrate 11 rapidly and evenly. In this embodiment, the heat-conducting film 13 is an aluminum oxide film. A thickness of the heat-conducting film 13 is in a range from about 0.025 mm to about 0.05 mm.

In other embodiment, the heat-conducting film 13 may be only formed on a bottom surface of the heat sink 10 for contacting an electronic component 31, i.e. CPU or GPU, so long as the heat-conducting film 13 can transfer heat of the electronic component 31 to the heat-conducting substrate 11 rapidly and evenly.

In the present disclosure, the heat conductivity coefficient of the heat-conducting film 13 is higher than that of the heat-conducting substrate 11, so that a heat conductivity coefficient of the heat sink 10 is higher than that of a conventional aluminum heat-dissipating plate having the same size, and a heat resistance of the heat sink 10 is lower than that of the conventional aluminum heat-dissipating plate. In use, a part of the heat-conducting film 13 formed on the bottom surface of the heat-conducting substrate 11 rapidly absorbs heat of the electronic component 31 and transfers the heat to the heat-conducting substrate 11 and another parts of the heat-conducting film 13 to dissipate rapidly and evenly.

The present disclosure further provides a method for manufacturing the heat sink 10 (shown in FIG. 1). The method for manufacturing the heat sink 10 includes following steps:

Step 1: providing a heat-conducting substrate 11 and cleaning a surface of the substrate 11 by alcohol or ionized water. The substrate 11 may be made by stamping or casting a metal plate.

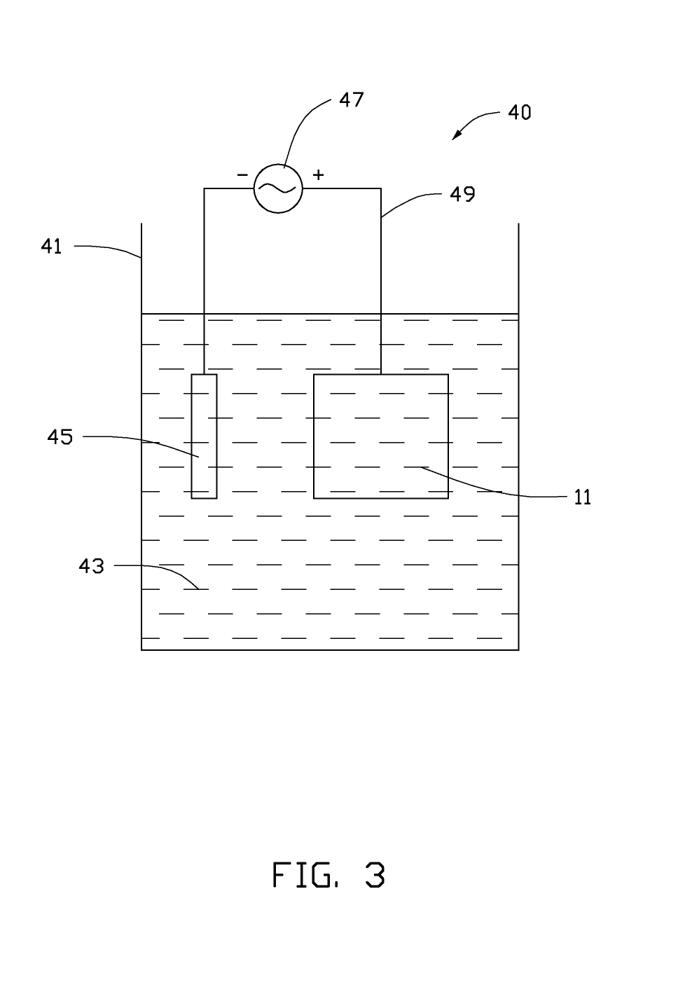

Step 2: Referring to FIG. 3, providing a micro-arc oxidation device 40, and oxidizing the heat-conducting substrate 11 in the micro-arc oxidation device 40 to form the heat-conducting film 13 on the outer periphery of the heat-conducting substrate 11. The micro-arc oxidation device 40 includes an oxidation tank 41, electrolyte 43 received in the oxidation tank 41, an electric conductor 45, a power source 47 and a plurality of wires 49 electrically connecting the electric conductor 45 and the heat-conducting substrate 11 to the power source 47. Specifically, connecting the heat-conducting substrate 11 to a positive electrode of the power source 47 and connecting the electric conductor 45 to a negative electrode of the power source 47, and immersing the electric conductor 45 and the heat-conducting substrate 11 in the electrolyte 43; turning on the power source 47, and oxidizing the heat-conducting substrate 11 in the oxidation tank 41. In this embodiment, the voltage of the power source 47 is in a range about from 300 volts to 500 volts, the oxidizing time is in a range from about 10 minutes to about 15 minutes, the temperature of the electrolyte 43 is in a range from about 20 Celsius degrees to about 40 Celsius degrees, and the thickness of the heat-conducting film 13 on the surface of the heat-conducting substrate 11 is varied between 0.025 mm-0.05 mm.

In order to compare the heat-dissipating capability of the heat sink 10 and the conventional aluminum plate having the same size as the heat sink 10, a testing method between the heat sink 10 and the conventional aluminum plate is shown as follows:

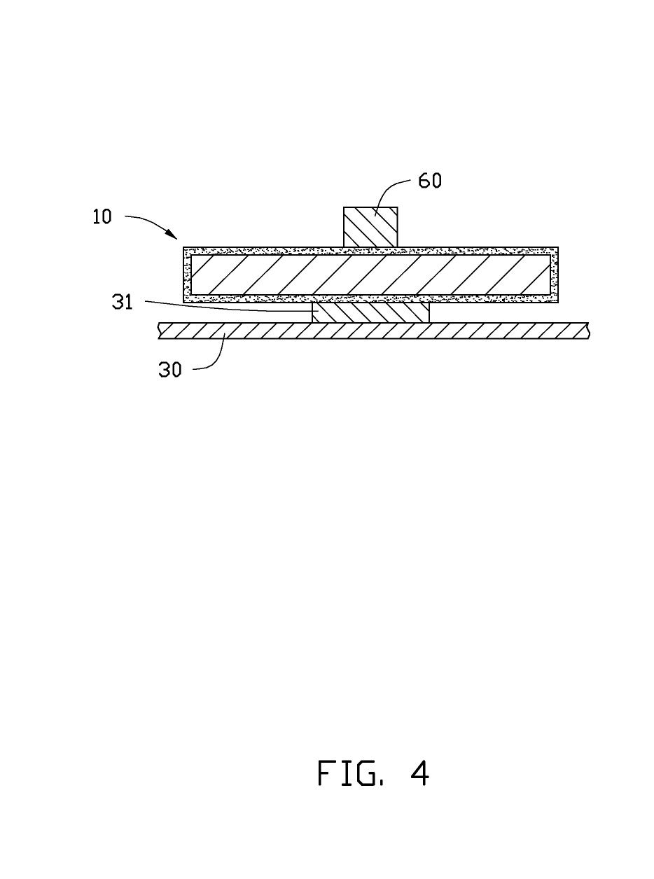

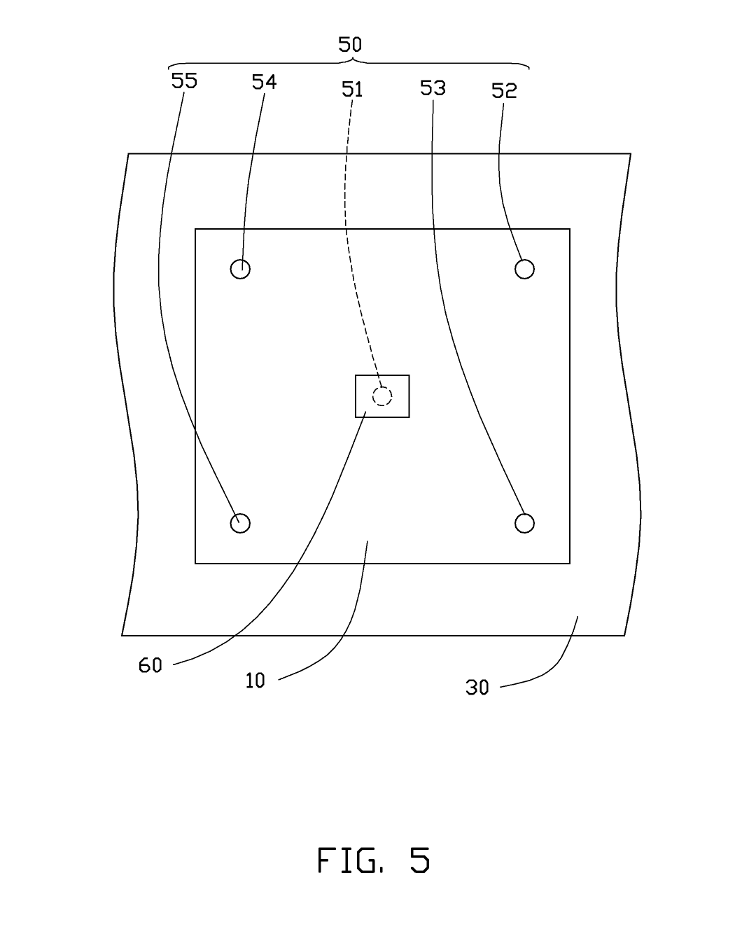

Step 1: referring to FIG. 4 and FIG. 5, providing the heat sink 10, and positing the heat sink 10 on the electronic component 31 of the printed circuit board 30. Preferably, the electronic component 31 is located at a center of the bottom surface of the heat sink 10. A fixture 60 is placed on a center of a top surface of the heat sink 10 to press the heat sink 10 intimately contacting the electronic component 31. The fixture 60 is made of materials with high heat resistance. In this embodiment, the fixture 60 is made of phenolic plastics, and the size of the heat sink 10 is 50 mm×50 mm.

Step 2: setting a certain working watt for the electronic component 31 to make it work in a stable condition. In this embodiment, the working watt of the electronic component 31 is varied between 2.49-2.53 watts.

Step 3: testing and recording the temperatures of the predetermined testing points 50. The predetermined testing points 50 includes a first reference point 51, a second testing point 52, a third testing point 53, a fourth testing point 54 and a fifth testing point 55. Preferably, the first reference point 51 is in a center of the top surface of the heat sink 10. Each of the first, second, third, fourth and fifth testing points 52, 53, 54, 55 on the top surface of the heat sink 10 has an equal distance away from the first reference point 51. In this embodiment, each of the testing points 52, 53, 54, 55 is located at one of four corners of the top surface. The temperature of the first reference point 51 is signed T01, the temperature of the second testing point 52 is signed T02, the temperature of the third testing point 53 is signed T03, the temperature of the forth testing point 54 is signed T04, and the temperature of the fifth testing point 55 is signed T05.

Step 4: providing a conventional aluminum plate (not shown) which has the same size as the heat sink 10 and testing the heat-dissipating capability of the conventional aluminum plate in the same method described above. The temperature of the first reference point 51 is signed T11, and the temperature of the second testing point 52 to the fifth testing point 55 are signed T12, T13, T14, T15 correspondingly.

Step 5: according to the temperatures of the predetermined testing points 50 and the watts of the electronic component 31, figuring out the heat resistance of the heat sink 10 and the conventional aluminum plate with different thickness, as shown in TABLE 1, and figuring out the temperature differences between the first reference point 51 and each of the testing points 52, 53, 54, 55 on the heat sink 10 and the conventional aluminum plate, as shown in TABLE 2.

TABLE 1 shows heat resistance comparison between the heat sink 10 and the conventional aluminum plate with different thicknesses.

TABLE 1

| Heat resistance | Thickness (mm) | | | | | | |
|---|---|---|---|---|---|---|---|
| (° C./W) | 0.06 | 0.1 | 0.15 | 0.2 | 0.3 | 0.4 | 0.5 |
| Conventional | 27.94 | 25.06 | 23.48 | 24.18 | 22.89 | 22.69 | 23.13 |
| aluminum plate | | | | | | | |
| Heat sink 10 | 26.40 | 24.03 | 22.73 | 21.70 | 21.62 | 21.29 | 20.60 |

TABLE 2 shows a relationship between the temperature differences among the testing points 50 on the heat sink 10 and the conventional aluminum plate with different thicknesses.

TABLE 2

| Temperature | Thickness (mm) | | | | | | |
|---|---|---|---|---|---|---|---|
| difference(° C.) | 0.06 | 0.1 | 0.15 | 0.2 | 0.3 | 0.4 | 0.5 |
| T01 − T02 (° C.) | 11.7 | 5.6 | 1.8 | 1.6 | 1.3 | 1.5 | 0.3 |
| T11 − T12 (° C.) | 12.3 | 6.2 | 3.9 | 3.2 | 6.6 | 5.1 | 7.1 |
| T01 − T03 (° C.) | 14.3 | 8.2 | 5.6 | 4.9 | 4.8 | 2.3 | 1.7 |
| T11 − T13 (° C.) | 15.6 | 9.0 | 5.8 | 5.4 | 7.2 | 5.7 | 8.5 |
| T01 − T04 (° C.) | 17.6 | 15.2 | 10.2 | 6.5 | 7.3 | 3.5 | 3.5 |
| T11 − T14 (° C.) | 25.0 | 15.8 | 11.3 | 7.6 | 8.7 | 6.4 | 11.3 |
| T01 − T05 (° C.) | 26.1 | 16.5 | 10.7 | 8.6 | 8.2 | 4.9 | 4.5 |
| T11 − T15 (° C.) | 26.7 | 17.0 | 11.5 | 10.6 | 9.7 | 7.3 | 9.3 |

As seen from TABLE 1, within the same thickness, a heat resistance of the heat sink 10 is lower than that of the conventional aluminum plate. Comparing with the conventional aluminum plate, the heat-conducting film 13 of the heat sink 10 absorbs the heat from the electronic component 31, and transfers the heat to the heat-conducting substrate 11 to dissipate more evenly and rapidly.

Besides, the heat resistances of the heat sink 10 decreases gradually with the increase of the thickness of the heat-conducting substrate 11. In a range from 0.06 mm to 0.5 mm, when the thickness of the heat-conducting substrate 11 is 0.5 mm, the difference of the heat resistance between the heat sink 10 and the conventional aluminum plate reaches the maximum, and the heat resistance of the heat sink 10 made by micro-arc oxidation reaches the minimum 20.60 V/W approximately.

Using a letter Y to sign the heat resistance of the heat sink 10 with a unit of ° C./W, and using a letter X to sign the thickness of the heat-conducting substrate 11 with a unit of mm, we can figure out the relationship between Y and X is Y=−10.41X+25.16, through a least square method. According to the relationship between Y and X, when the thickness of the heat-conducting substrate 11 is close to 2.4 mm, the heat resistance of the heat sink 10 is close to the minimum accordingly. However, since the heat sink 10 is used to enhance the capability of heat-dissipating for electric products, the thickness of the heat-conducting substrate 11 may be altered according to actual requirement.

According to TABLE 2, within the same thickness of the heat sink 10 and the conventional aluminum plate, the temperature differences between the first reference testing point 51 and each of another testing points 52,53,54,55 on the heat sink 10 is smaller than that of conventional aluminum plate. It means that, on a same condition, the heat from the center of the top surface of the heat sink 10, which is conducted from the bottom surface of the heat sink 10, can be dissipated more evenly and rapidly than that of the conventional aluminum plate.

It is to be understood, however, that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink, comprising:
a heat-conducting substrate; and
a heat-conducting film formed on an outer surface of the heat-conducting substrate, a heat conductivity coefficient of the heat-conducting film being higher than that of the heat-conducting substrate, the heat-conducting film being thinner than the heat-conducting substrate, and a thickness of the heat-conducting film is in a range from about 0.025 mm to about 0.05 mm.

2. The heat sink of claim 1, wherein the heat-conducting film is formed on a part of the outer surface of the heat-conducting substrate.

3. The heat sink of claim 1, wherein the heat-conducting film entirely covers the outer surface of the heat-conducting substrate.

4. The heat sink of claim 1, wherein the heat-conducting substrate is made of aluminum.

5. The heat sink of claim 4, wherein the heat-conducting film is an aluminum oxide film with uniform thickness.

6. The heat sink of claim 4, wherein the heat-conducting film is a ceramic film.

7. A method for manufacturing a heat sink, comprising:
providing a heat-conducting substrate;
forming a heat-conducting film on an outer surface of the heat-conducting substrate, a heat conductivity coefficient of the heat-conducting film being higher than that of the heat-conducting substrate, and a thickness of the heat-conducting film is in a range from about 0.025 mm to about 0.05 mm.

8. The method of claim 7, wherein the heat-conducting film is formed on a part of the outer surface of the heat-conducting substrate.

9. The method of claim 7, wherein the heat-conducting film entirely covers the outer surface of the heat-conducting substrate.

10. The method of claim 7, wherein the heat-conducting substrate is made of aluminum.

11. The method of claim 10, wherein the heat-conducting film is an aluminum oxide film or ceramic film with uniform thickness.

12. The method of claim 7, wherein the step of forming the heat-conducting film on the outer surface of the substrate comprises providing a micro-arc oxidation device, the micro-arc oxidation device including a oxidation tank, electrolyte in the oxidation tank, an electric conductor and a power source, the electric conductor and the heat-conducting substrate being electrically connecting the power source, and oxidizing the heat-conducting substrate in the electrolyte to form the heat-conducting film on the outer surface of the heat-conducting substrate.

13. The method of claim 12, wherein the temperature of the electrolyte is in a range from about 20° C. to about 40° C.

14. The method of claim 12, wherein the voltage of the power source is in a range from 300 volts to 500 volts.

15. The method of claim 12, wherein the oxidizing time is in a range from about 10 minutes to about 15 minutes.

16. A method for testing a heat-dissipating capability of a heat sink and a conventional aluminum plate, the heat sink comprising a heat-conducting substrate, and a heat-conducting film formed on an outer surface of the heat-conducting substrate, a heat conductivity coefficient of the heat-conducting film being higher than that of the heat-conducting substrate, the conventional aluminum plate having the same size as the heat sink, the method comprising:
positing the heat sink on an electronic component;
setting a certain working watt for the electronic component to make it work in a stable condition;
testing and recording the temperatures of predetermined testing points, the predetermined testing points include a reference point, and a plurality of testing points;
testing the heat-dissipating capability of the conventional aluminum plate in the same method described above; and
according to the temperatures of the predetermined testing points and the watts of the electronic component, figuring out the heat resistance of the heat sink and the conventional aluminum plate with different thickness, and the temperature differences between the reference point and each of the testing points on the heat sink and the conventional aluminum plate.

17. The method of claim 16, wherein the electronic component is located at a center of a bottom surface of the heat sink, the reference point is positioned in a center of a top surface of the heat sink, and each of the testing points on the top surface of the heat sink has an equal distance away from the reference point.

18. The method of claim 17, wherein a fixture is placed on the center of the top surface of the heat sink to press the heat sink intimately contacting the electronic component.

19. The method of claim 17, wherein a number of the testing points is four, each of the testing points is located at one of four corners of the top surface of the heat sink.

20. The method of claim 16, wherein the working watt of the electronic component is in a range from 2.49 to 2.53 watts.
